(19) United States
(12) Patent Application Publication
(10) Pub. No.: US 2025/0359461 A1
(43) Pub. Date: Nov. 20, 2025

(54) DISPLAY DEVICE, METHOD OF MANUFACTURING DISPLAY DEVICE, AND ELECTRONIC DEVICE COMPRISING DISPLAY DEVICE

(71) Applicant: Samsung Display Co., Ltd., Yongin-Si (KR)

(72) Inventor: Hee Min PARK, Yongin-si (KR)

(21) Appl. No.: 19/002,691

(22) Filed: Dec. 27, 2024

(30) Foreign Application Priority Data
May 20, 2024 (KR) 10-2024-0065098

(51) Int. Cl. H10K 59/80; H10K 59/12; H10K 71/40; H10K 71/60; H10K 102/00

(52) U.S. Cl. CPC H10K 59/80517; H10K 59/1201; H10K 71/40; H10K 71/60; H10K 2102/351

(57) ABSTRACT

A display device, a method of manufacturing the display device, and an electronic device comprising the display device are provided. The display device includes a base layer, and a light emitting element disposed on the base layer, and including a first electrode, a light emitting layer electrically connected to the first electrode, and a second electrode electrically connected to the light emitting layer. The first electrode includes a lower electrode disposed between the light emitting layer and the base layer, an intermediate electrode on the lower electrode, and an upper electrode on the intermediate electrode. The intermediate electrode includes an intermediate base electrode and a protruding portion protruding in a thickness direction of the base layer, the intermediate electrode including aluminum (Al).

This application claims priority to Korean Patent Application No. 10-2024-0065098 filed on May 20, 2024 in the Korean Intellectual Property Office, the disclosure of which is incorporated by reference herein in its entirety.

### BACKGROUND

### 1. Field

The disclosure relates to a display device, a method of manufacturing the display device, and an electronic device comprising the display device.

### 2. Description of the Related Art

Recently, as interest in information display is increased, research and development on a display device is continuously being conducted.

### SUMMARY

An aspect of the disclosure is to provide a display device, a method of manufacturing the display device, and an electronic device comprising the display device in which light emission efficiency may be improved and a luminance characteristic may be improved.

An aspect of the disclosure is to provide a display device, a method of manufacturing the display device, and an electronic device comprising the display device in which a process efficiency is improved.

According to an embodiment of the disclosure, a display device may include a base layer, and a light emitting element disposed on the base layer, and including a first electrode, a light emitting layer electrically connected to the first electrode, and a second electrode electrically connected to the light emitting layer. The first electrode may include a lower electrode disposed between the light emitting layer and the base layer, an intermediate electrode on the lower electrode, and an upper electrode on the intermediate electrode. The intermediate electrode may include an intermediate base electrode and a protruding portion protruding in a thickness direction of the base layer, wherein the intermediate electrode includes aluminum (Al).

According to an embodiment, the protruding portion may form a reflective surface extending in a direction inclined with respect to the thickness direction of the base layer.

According to an embodiment, a diameter of the protruding portion may be 400 nm to 600 nm. A height of the protruding portion may be 200 nm to 300 nm.

According to an embodiment, the protruding portion may include a plurality of protruding portions. The plurality of protruding portions may be formed to have a density of 107 to 108 per unit area [mm2] on the intermediate base electrode.

According to an embodiment, the protruding portion may include a plurality of protruding portions. The plurality of protruding portions may be randomly formed on the intermediate base electrode.

According to an embodiment, the lower electrode and the upper electrode may include a transparent conductive material.

According to an embodiment, the upper electrode may have a thickness that is less than that of the intermediate electrode. The upper electrode may form a protruding portion structure that matches the contours of the protruding portion.

According to an embodiment, the upper electrode may include a first upper electrode and a second upper electrode including different materials. The first upper electrode may have a thickness less than that of the intermediate electrode and forms a first protruding portion structure having contours that match the contours of the protruding portion. The second upper electrode may have a thickness less than that of the intermediate electrode and forms a second protruding portion structure having contours that match the contours of the protruding portion.

According to an embodiment, the display device may include a first sub-pixel area where light of a first color is provided, a second sub-pixel area where light of a second color is provided, and a third sub-pixel area where light of a third color is provided. The light emitting element may include a first light emitting element in the first sub-pixel area, a second light emitting element in the second sub-pixel area, and a third light emitting element in the third sub-pixel area. The first light emitting element may provide the light of the first color, the second light emitting element may provide the light of the second color, and the third light emitting element may provide the light of the third color.

According to an embodiment of the disclosure, a display device may include a base layer, and a light emitting element disposed on the base layer, and including a first electrode, a light emitting layer electrically connected to the first electrode, and a second electrode electrically connected to the light emitting layer. The first electrode may be disposed between the light emitting layer and the base layer, and may include a lower electrode, an intermediate electrode on the lower electrode, and an upper electrode on the intermediate electrode. The intermediate electrode may include an intermediate base electrode layer and a protruding portion protruding in a thickness direction of the base layer. The protruding portion may have a diameter of 400 nm to 600 nm in plan view.

According to an embodiment of the disclosure, a method of manufacturing a display device may include forming a first electrode on a base layer, forming a light emitting layer on the first electrode, and forming a second electrode on the light emitting layer. Forming the first electrode may include patterning a lower electrode on the base layer, patterning an intermediate base electrode on the lower electrode, forming protruding portions on the intermediate base electrode by performing a heat treatment process on the intermediate base electrode, and patterning an upper electrode on the protruding portions and the intermediate base electrode.

According to an embodiment, the intermediate base electrode and the protruding portions may include aluminum (Al). The lower electrode and the upper electrode may include indium tin oxide (ITO).

According to an embodiment, a temperature range at which the heat treatment process is performed may be 100° C. to 300° C.

According to an embodiment, forming the protruding portions may include patterning the protruding portions on the intermediate base electrode without performing an etching process.

According to an embodiment, patterning the upper electrode may include forming a protruding portion structure by the upper electrode without performing an additional heat treatment process.

According to an embodiment, forming the protruding portions may be performed after patterning the intermediate base electrode.

According to an embodiment, forming the protruding portions and patterning the intermediate base electrode may be performed in the same process.

According to an embodiment, forming the protruding portions may include adjusting a temperature in a chamber for forming the intermediate base electrode.

According to an embodiment, the protruding portions and the intermediate base electrode may form an intermediate electrode. Patterning the upper electrode may include forming a first upper electrode and forming a second upper electrode on the first upper electrode. Forming the first upper electrode may include forming a first protruding portion structure on the intermediate electrode without performing an additional heat treatment process. Forming the second upper electrode may include forming a second protruding portion structure on the intermediate electrode without performing an additional heat treatment process.

According to an embodiment of the disclosure, the electronic device may comprise: a processor configured to provide input image data; a display device configured to display an image based on the input image data, the display device including sub-pixel areas; and a power supply configured to supply power to the display device. The display device may include a base layer, and a light emitting element disposed on the base layer, and including a first electrode, a light emitting layer electrically connected to the first electrode, and a second electrode electrically connected to the light emitting layer. The first electrode may include a lower electrode disposed between the light emitting layer and the base layer, an intermediate electrode on the lower electrode, and an upper electrode on the intermediate electrode. The intermediate electrode may include an intermediate base electrode and a protruding portion protruding in a thickness direction of the base layer, wherein the intermediate electrode includes aluminum (Al).

According to an embodiment of the disclosure, a display device, a method of manufacturing the display device, and an electronic device comprising the display device in which light emission efficiency may be improved and a luminance characteristic may be improved may be provided.

According to an embodiment of the disclosure, a display device, a method of manufacturing the display device, and an electronic device comprising the display device in which a process efficiency is improved may be provided.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view illustrating a display device according to an embodiment;

FIGS. 2 and 3 are schematic cross-sectional views illustrating a display device according to an embodiment;

FIG. 4 is a schematic cross-sectional view illustrating a light emitting element according to an embodiment;

FIGS. 5 and 6 are schematic cross-sectional views illustrating a display device according to an embodiment;

FIG. 7 is a graph illustrating a reflectance characteristic of various metal materials for each wavelength band of light;

FIG. 8 is a schematic enlarged cross-sectional view illustrating a first electrode according to an embodiment;

FIG. 9 illustrates a plane image of an intermediate electrode according to a heat treatment process temperature for manufacturing the intermediate electrode according to an embodiment;

FIG. 10 is a graph illustrating a normalized scattering cross section for each wavelength band of light according to a diameter of a protruding portion of an intermediate electrode according to the embodiment;

FIG. 11 is a graph illustrating a relative luminance of light provided according to a density of a protruding portion of an intermediate electrode according to an embodiment;

FIG. 12 is a flowchart illustrating a method of manufacturing a display device according to an embodiment;

FIG. 13 is a flowchart illustrating a step of manufacturing a light emitting element layer according to an embodiment;

FIGS. 14 to 18 are schematic cross-sectional views for each process illustrating a method of manufacturing a display device according to an embodiment;

FIG. 19 is a flowchart illustrating a step of manufacturing a light emitting element layer according to an embodiment; and

FIGS. 20 and 21 are schematic cross-sectional views for each process illustrating a method of manufacturing a display device according to an embodiment.

FIG. 22 is a schematic block diagram illustrating an electronic device including a display device in accordance with an embodiment.

FIG. 23 is a schematic diagram illustrating an example where the electronic device of FIG. 22 is implemented as a smartphone.

FIG. 24 is a schematic diagram illustrating an example where the electronic device of FIG. 22 is implemented as a tablet computer.

### DETAILED DESCRIPTION OF THE EMBODIMENT

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Ordinal terms of “first”, “second”, and the like may be used to describe various components, but the components should not be limited to any order or priority by the terms. The terms are used for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it includes not only a case where the portion is “directly on” another portion, but also a case where there is further another portion between the portion and the other portion. In addition, in the present specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and the other portion.

The disclosure relates to a display device, a method of manufacturing the display device, and an electronic device comprising the display device. Hereinafter, a display device according to an embodiment is described with reference to the accompanying drawings.

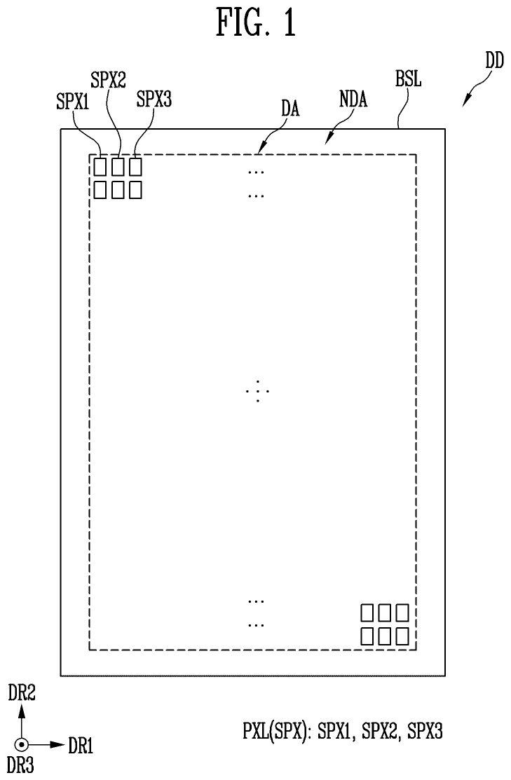

FIG. 1 is a schematic plan view illustrating a display device according to an embodiment.

Referring to FIG. 1, the display device DD may include a base layer BSL and a pixel PXL disposed on the base layer BSL. The display device DD may further include a driving circuit unit (for example, a scan driver and a data driver), lines, and pads for driving the pixel PXL.

The display device DD (or the base layer BSL) may include a display area DA and a non-display area NDA. The non-display area NDA may mean an area other than the display area DA. The non-display area NDA may surround at least a portion of the display area DA.

The base layer BSL may form a base surface of the display device DD. According to an embodiment, the base layer BSL may be a lower substrate for disposing layers forming the display device DD. The base layer BSL may be a rigid or flexible substrate or film. For example, the base layer BSL may include a glass material. Alternatively, the base layer BSL may include a silicon material. Alternatively, the base layer BSL may include polyimide. However, the disclosure is not limited thereto.

The display area DA may mean an area where the pixel PXL is disposed. The non-display area NDA may mean an area where the pixel PXL is not disposed. The driving circuit unit, the line, and the pads connected to the pixel PXL of the display area DA may be disposed in the non-display area NDA.

According to an embodiment, the pixel PXL (or sub-pixels SPX) may be arranged according to a stripe or PENTILE™ arrangement structure, but are not limited thereto, and various embodiments may be applied to the disclosure.

According to an embodiment, the pixel PXL (or the sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one of the first sub-pixel SPX1, the second sub-pixel SPX2, and the third sub-pixel SPX3 may form a pixel unit capable of emitting light of various colors.

Each of the first sub-pixel SPX1, the second sub-pixel SPX2, and the third sub-pixel SPX3 may emit light of a color.

For example, the first sub-pixel SPX1 may be a red pixel emitting red light, the second sub-pixel SPX2 may be a green pixel emitting green light, and the third sub-pixel SPX3 may be a blue pixel emitting blue light. The red pixel may provide light of a wavelength range of 600 nm to 750 nm. The green pixel may provide light of a wavelength band of 480 nm to 560 nm. The blue pixel may provide light of a wavelength range of 370 nm to 460 nm. The sub-pixels SPX1, SPX2, and SPX3 are not limited to emitting the specific colors of light described above, and may emit light of a first color, a second color, and a third color, respectively.

According to an embodiment, the number of second sub-pixels SPX2 may be greater than the number of first sub-pixels SPX1 and the number of third sub-pixels SPX3. However, the color, type, number, and/or the like of the first sub-pixel SPX1, the second sub-pixel SPX2, and the third sub-pixel SPX3 forming each pixel unit are/is not limited to a specific example.

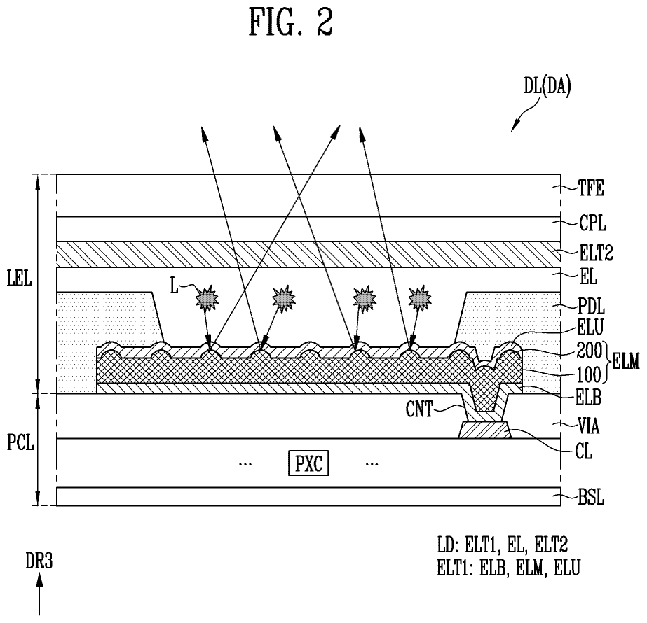

With reference to FIGS. 2 to 4, a cross-sectional structure of the display device DD according to an embodiment is described.

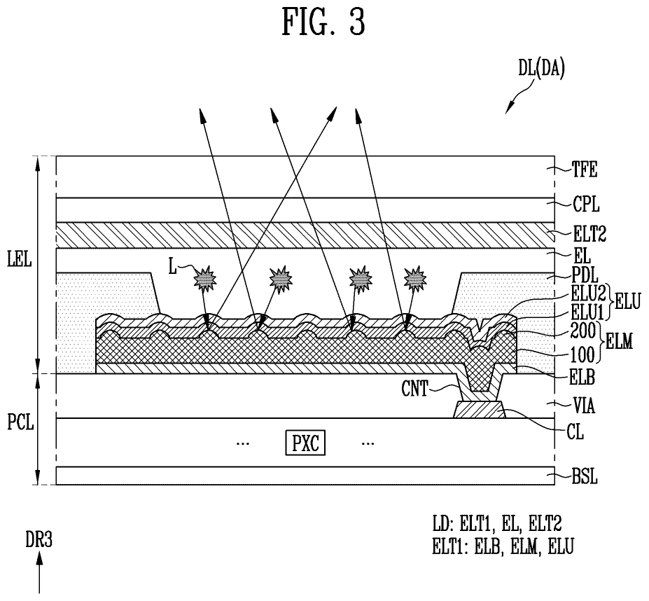

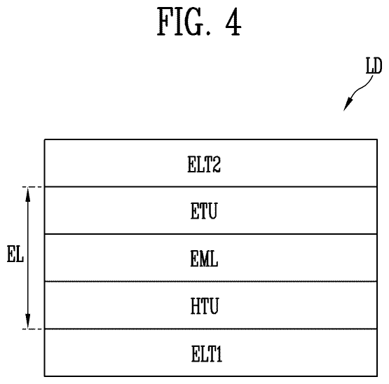

FIGS. 2 and 3 are schematic cross-sectional views illustrating a display device according to an embodiment. FIGS. 2 and 3 show a portion of the display device DD in the display area DA. FIG. 2 is a schematic cross-sectional view illustrating a display layer DL included in the display device DD according to an embodiment. FIG. 3 is a schematic cross-sectional view illustrating a display layer DL included in a display device DD according to another embodiment. FIG. 4 is a schematic cross-sectional view illustrating a light emitting element according to an embodiment.

Referring to FIGS. 2 to 4, the display device DD may include the display layer DL configured to provide light.

The display layer DL may include a pixel circuit layer PCL including the base layer BSL, and a light emitting element layer LEL that may form the pixel PXL by including a light emitting element LD.

The base layer BSL may form a base on which a pixel circuit PXC is disposed. The pixel circuit PXC may be disposed on the base layer BSL and may be configured to drive the light emitting element LD. The pixel circuit layer PCL may include conductive layers and insulating layers, and the conductive layers may form the pixel circuit PXC. The pixel circuit PXC may include circuit elements capable of driving a sub-pixel SPX (or the light emitting element LD). The circuit elements may include a driving transistor and may include additional transistor and capacitors. According to an embodiment, the pixel circuit layer PCL may include a conductive layer CL and a via layer VIA. The conductive layer CL may be a source electrode and/or a drain electrode. For example, the conductive layer CL may be a portion of the pixel circuit PXC or may be electrically connected to the pixel circuit PXC. The via layer VIA may be a planarization layer and may form a contact portion CNT that electrically connects a first electrode ELT1 of the light emitting element LD and the conductive layer CL. The via layer VIA may include an organic material, but the disclosure is not limited thereto. The via layer VIA may form a base on which the light emitting element layer LEL is disposed. The via layer VIA may be referred to as a protective layer.

The light emitting element layer LEL may be disposed on the pixel circuit layer PCL (for example, the via layer VIA).

According to an embodiment, the light emitting element layer LEL may include the light emitting element LD. The light emitting element layer LEL may further include a pixel defining layer PDL, a capping layer CPL, and an encapsulation layer TFE.

The light emitting element LD may include an organic light emitting diode OLED including an organic material.

The light emitting element LD may include the first electrode ELT1, a light emitting layer EL, and a second electrode ELT2. A first surface (for example, a lower surface) of the light emitting layer EL may be electrically connected to the first electrode ELT1, and a second surface (for example, an upper surface) of the light emitting layer EL may be electrically connected to the second electrode ELT2.

The first electrode ELT1 may be a lower electrode of the light emitting element LD. The first electrode ELT1 may be disposed between the light emitting layer EL and the base layer BSL. The first electrode ELT1 may be disposed on the base layer BSL and may be partially covered by the pixel defining layer PDL. According to an embodiment, the first electrode ELT1 may be an anode. According to an embodiment, the first electrode ELT1 may be electrically connected to the pixel circuit PXC (for example, the conductive layer CL) through the contact portion CNT.

The first electrode ELT1 may have a multilayer structure. For example, the first electrode ELT1 may include a lower electrode ELB, an intermediate electrode ELM, and an upper electrode ELU that overlap each other.

A “plane” as used in this specification may be a plane defined by a first direction DR1 and a second direction DR2 and may be a plane in which the base layer BSL is disposed. The expression “in plan view” refers to a view of the plane from the top. According to an embodiment, a third direction DR3 may be referred to as a “thickness” direction of the base layer BSL, and the third direction DR3 may be a light emission direction of the display device DD.

The lower electrode ELB may be disposed on the via layer VIA. A portion of the lower electrode ELB may form the contact portion CNT and may be electrically connected to the conductive layer CL. The lower electrode ELB may form a base on which an intermediate base electrode 100 of the intermediate electrode ELM is disposed.

An upper surface of the lower electrode ELB may have a generally flat surface. For example, the lower electrode ELB may not include a protruding portion structure.

The lower electrode ELB may properly bond the via layer VIA and the first electrode ELT1 to each other.

The lower electrode ELB may include a transparent conductive material. For example, the lower electrode ELB may include at least one of a group of indium tin oxide (ITO), silver nanowire (AgNW), indium zinc oxide (IZO), indium gallium zinc oxide (IGZO), aluminum zinc oxide (AZO), indium tin zinc oxide (ITZO), zinc oxide (ZnO), tin oxide (SnO2), carbon nano tube, and graphene. For example, the lower electrode ELB may include ITO. However, the disclosure is not necessarily limited thereto.

The intermediate electrode ELM may be disposed between the lower electrode ELB and the upper electrode ELU. The intermediate electrode ELM may be a reflective layer. For example, the intermediate electrode ELM may include a reflective conductive material.

The intermediate electrode ELM may include a protruding portion 200 that improves a light emission efficiency of the light emitting element LD and the intermediate base electrode 100 that provides a base on which the protruding portion 200 is formed.

A lower surface of the intermediate base electrode 100 may be directly adjacent to the lower electrode ELB and may have a generally flat surface. An upper surface of the intermediate base electrode 100 may be directly adjacent to the protruding portion 200. According to an embodiment, the intermediate base electrode 100 and the protruding portion 200 may be integrally formed.

The protruding portion 200 may have a shape that generally protrudes in a thickness direction (for example, the third direction DR3) of the base layer BSL. For example, the protruding portion 200 may have a hemispherical cross-sectional shape.

The protruding portion 200 may more efficiently reflect light L applied from the light emitting layer EL in a display direction (for example, the third direction DR3) of the display device DD. The protruding portion 200 may form a reflective surface extending in a direction inclined with respect to the thickness direction (for example, third direction DR3) of the base layer BSL.

Experimentally, when the intermediate electrode ELM forms a flat upper surface without formation of the protruding portion 200, a risk that light loss occurs may exist due to interaction between a metal forming the intermediate electrode ELM and the light L (for example, surface plasmon polaritons) resonance. However, according to an embodiment, light propagated along a surface of the intermediate electrode ELM may not be propagated to another adjacent surface by the protruding portion 200 and may be output to an outside of the display device DD. Accordingly, the light loss risk described above may be reduced.

According to an embodiment, as the intermediate electrode ELM includes the protruding portion 200, a reflective surface formed by the intermediate electrode ELM may be expanded, and thus the light L may be generally provided in the display direction of the display device DD. Accordingly, a light emission efficiency and a luminance characteristic of the display device DD may be improved.

According to an embodiment, as the intermediate electrode ELM includes the protruding portion 200, at least a portion of the intermediate electrode ELM may include a reflective surface extending in a direction inclined with respect to the third direction DR3, and a light amount output in a diagonal direction (for example, a side surface direction) with respect to the third direction DR3 may increase. Accordingly, optical information provided by the display device DD may be appropriately provided to each of a front surface and a side surface.

According to an embodiment, as the intermediate electrode ELM includes the protruding portion 200, the applied light L may be scattered in two or more directions. For example, the protruding portion 200 may be a scattering structure for the light L provided from the light emitting layer EL. According to an embodiment, the intermediate electrode ELM including a metal material may improve the scattering characteristic, and thus a viewing angle characteristic of the display device DD may be improved.

The protruding portion 200 may include a plurality of protruding portions 200, and the number of protruding portions 200 is not limited to any specific embodiment that is depicted.

According to an embodiment, the plurality of protruding portions 200 may be disposed on the intermediate base electrode 100 at a density of 10⁷ to 10⁸ [number/mm²]. According to an embodiment, the plurality of protruding portions 200 may be disposed on the intermediate base electrode 100 at a density of 10⁷ to 5×10⁷ [number/mm²]. When the density at which the plurality of protruding portions 200 are formed satisfies the numerical range described above, a relatively excellent luminance characteristic may be implemented.

According to an embodiment, the plurality of protruding portions 200 may be formed through heat treatment in a process environment set to a predetermined temperature range rather than an etching process. Accordingly, the plurality of protruding portions 200 may be randomly formed on the intermediate base electrode 100. That is, since the plurality of protruding portions 200 according to an embodiment may be manufactured without requiring an additional mask, a process step may be simplified and a process cost may be reduced in a method of manufacturing the display device DD according to an embodiment. In addition, when the plurality of protruding portions 200 are randomly formed on the intermediate base electrode 100, a light scattering effect may be further improved, and thus the light emission efficiency may be further improved.

According to an embodiment, the protruding portion 200 may be referred to as an uneven structure. The protruding portion 200 may be referred to as a hillock.

The protruding portion 200 may be formed by performing a heat treatment process on the intermediate base electrode 100.

According to an embodiment, the intermediate electrode ELM may include a conductive material suitable for forming the protruding portion 200 through a heat treatment process. For example, the intermediate electrode ELM may include one or more of aluminum (Al), copper (Cu), tin (Sn), and lead (Pb). According to an embodiment, the intermediate electrode ELM may include aluminum (Al).

For example, after the intermediate base electrode 100 including aluminum (Al) is formed, a heat treatment process on the intermediate base electrode 100 may be performed. Alternatively, a heat treatment process may be performed when the intermediate base electrode 100 including aluminum (Al) is formed. In this case, the protruding portion 200 may be formed on the intermediate base electrode 100 due to stress applied to aluminum (Al).

According to an embodiment, as the intermediate electrode ELM includes aluminum (Al), the protruding portion 200 may be appropriately formed even though a heat treatment process is performed at a low temperature range. For example, the protruding portion 200 may be formed through a heat treatment process of a temperature range of 100° C. to 300° C. According to an embodiment, the protruding portion 200 may be formed through a heat treatment process of a temperature range of 100° C. to 200° C.

According to an embodiment, since the protruding portion 200 may be manufactured using a heat treatment process rather than an etching process, an additional process procedure may not be required. For example, a process temperature in a deposition chamber for manufacturing the intermediate base electrode 100 may be adjusted, and the protruding portion 200 may be formed on the intermediate base electrode 100.

According to an embodiment, the size and the number of protruding portions 200 may be controlled according to a temperature range of the heat treatment process. A detailed description regarding this process will be provided below.

The upper electrode ELU may be disposed on the intermediate electrode ELM. The upper electrode ELU may cover the intermediate base electrode 100 and the protruding portion 200. The upper electrode ELU may entirely cover the protruding portion 200. The upper electrode ELU may be covered by the pixel defining layer PDL and may be adjacent to (for example, directly adjacent to) the light emitting layer EL.

The upper electrode ELU may have a shape that generally matches the shape of the upper surface of the intermediate electrode ELM. For example, the upper electrode ELU may include an upper protruding portion structure that generally matches the shape of the intermediate base electrode 100 and the protruding portion 200. According to an embodiment, the upper electrode ELU may be formed after the intermediate electrode ELM including the intermediate base electrode 100 and the protruding portion 200 is disposed. At this time, the upper electrode ELU may be formed by a process of sputtering or the like and may have a relatively thin thickness. For example, the upper electrode ELU may have a thickness that is less than that of the intermediate electrode ELM. Accordingly, the upper electrode ELU may be formed to be relatively thin along an upper surface of the intermediate base electrode 100 and the protruding portion 200, and the upper electrode ELU may be formed to have an upper protruding portion structure having the same contours as the protruding portion 200. In some embodiments, the upper electrode ELU may be conformally formed on the intermediate electrode ELM. The upper electrode ELU may have a constant thickness. The upper protruding portion structure of the upper electrode ELU according to an embodiment may be manufactured without performing an additional heat treatment process or an etching process.

The upper electrode ELU may have a relatively high work function value and may reduce an oxidation risk for the intermediate electrode ELM disposed thereunder.

The upper electrode ELU may include a transparent conductive material. For example, the upper electrode ELU may include at least one of a group of indium tin oxide (ITO), silver nanowire (AgNW), indium zinc oxide (IZO), indium gallium zinc oxide (IGZO), aluminum zinc oxide (AZO), indium tin zinc oxide (ITZO), zinc oxide (ZnO), tin oxide (SnO2), carbon nano tube, and graphene. According to an embodiment, the upper electrode ELU may include the same material as the lower electrode ELB. For example, the upper electrode ELU may include ITO. However, the disclosure is not necessarily limited thereto.

The light emitting layer EL may be disposed on the first electrode ELT1. The light emitting layer EL may include a plurality of layers. For example, the light emitting layer EL may include a hole transport unit HTU, a light emitting unit EML (or a light generation layer), and an electron transport unit ETU. Each of the layers forming the light emitting layer EL may include an organic material, and according to an embodiment, may further include a metal-containing compound, an inorganic material such as a quantum dot, or the like.

The hole transport unit HTU may include a multilayer structure having a plurality of layers respectively including different materials. As an example, the hole transport unit HTU may include a hole injection layer and a hole transport layer, and according to an embodiment, may further include a light emitting auxiliary layer and an electron blocking layer.

The light emitting unit EML may include a material that may emit light of a color. The light emitting unit EML may include a host and a dopant. The host of the light emitting unit EML may be a light emitting material that may capture carriers (electrons and holes) for light generation and induce efficient generation of an exciton. The dopant may include a phosphorescent dopant or a fluorescent dopant. The dopant is not limited to what is explicitly disclosed herein. According to an embodiment, the dopant may include an organic material, and may include a metal complex or the like.

The electron transport unit ETU may include a multilayer structure having a plurality of layers respectively including different materials. The electron transport unit ETU may include an electron injection layer and an electron transport layer, and according to an embodiment, may further include an electron buffer layer, a hole blocking layer, and the like.

The second electrode ELT2 may be an upper electrode of the light emitting element LD. The second electrode ELT2 may be disposed on the light emitting layer EL. The second electrode ELT2 may be disposed on a front surface of the display area DA. The second electrode ELT2 may be a common electrode for different sub-pixels SPX. According to an embodiment, the second electrode ELT2 may be a cathode.

The second electrode ELT2 may include various conductive materials. For example, the second electrode ELT2 may include silver (Ag) and may further include an additional metal. The additional metal may include one or more of magnesium (Mg), aluminum (Al), copper (Cu), calcium (Ca), and barium (Ba). For example, the second electrode ELT2 may include silver-magnesium (AgMg) alloy. The additional metal may improve an aggregation phenomenon of silver (Ag) that functions as a host metal, and improve stability of a thin film formed by the second electrode ELT2. However, the disclosure is not limited thereto. According to an embodiment, the second electrode ELT2 may include one or more of various transparent conductive materials.

The pixel defining layer PDL may be disposed on the via layer VIA and the first electrode ELT1. The pixel defining layer PDL may define an area where the light emitting layer EL and the first electrode ELT1 are in electrical contact.

The pixel defining layer PDL may include an inorganic material. For example, the pixel defining layer PDL may include silicon oxide (SiOx) and silicon nitride (SiNx). However, the disclosure is not limited thereto. The pixel defining layer PDL may include a multilayer structure. For example, the pixel defining layer PDL may include a multilayer structure in which silicon oxide (SiOx) and silicon nitride (SiNx) are alternately disposed.

The capping layer CPL may be disposed on the second electrode ELT2. The capping layer CPL may passivate the light emitting element LD. The capping layer CPL may include an organic material. Alternatively, the capping layer CPL may include an inorganic material.

The encapsulation layer TFE may be disposed on the capping layer CPL. The encapsulation layer TFE may remove a step formed by the light emitting elements LD and passivate the light emitting elements LD.

The encapsulation layer TFE may include a multilayer structure. For example, the encapsulation layer TFE may include a first encapsulation layer, a second encapsulation layer, and a third encapsulation layer. According to an embodiment, the first encapsulation layer may include an inorganic material, the second encapsulation layer may include an organic material, and the third encapsulation layer may include an inorganic material. However, the disclosure is not limited thereto.

Meanwhile, referring to FIG. 3, according to an embodiment, the upper electrode ELU of the first electrode ELT1 may include two or more layers.

For example, the upper electrode ELU may include a first upper electrode ELU1 and a second upper electrode ELU2.

The first upper electrode ELU1 may be disposed on the intermediate electrode ELM. The first upper electrode ELU1 may have a structural characteristic similar to that of the intermediate electrode ELM described above with reference to FIG. 2. For example, the first upper electrode ELU1 may cover the intermediate base electrode 100 and the protruding portion 200. The first upper electrode ELU1 may entirely cover the protruding portion 200.

The first upper electrode ELU1 may have a contour matching the upper surface of the intermediate electrode ELM. For example, the first upper electrode ELU1 may include a first upper protruding portion structure having the same outline as the intermediate base electrode 100 and the protruding portion 200. According to an embodiment, the first upper electrode ELU1 may be formed after the intermediate electrode ELM including the intermediate base electrode 100 and the protruding portion 200 is disposed. At this time, the first upper electrode ELU1 may be formed through a process of sputtering or the like and may be relatively thin. For example, the first upper electrode ELU1 may have a thickness that is less than that of the intermediate electrode ELM. Accordingly, the first upper electrode ELU1 may be formed to be relatively thin along an upper surface of the intermediate base electrode 100 and the protruding portion 200, and the first upper electrode ELU1 may be formed to have the first upper protruding portion structure following the contours of the protruding portion 200. In some embodiments, the first upper electrode ELU1 may be conformally formed on the intermediate electrode ELM. The first upper electrode ELU1 may have a constant thickness. The first upper protruding portion structure of the first upper electrode ELU1 according to an embodiment may be manufactured without performing an additional heat treatment process or an etching process.

The first upper electrode ELU1 may include a reflective conductive material different from that of the intermediate electrode ELM. In one embodiment, the intermediate electrode ELM may include aluminum (Al), and the first upper electrode ELU1 may include silver (Ag).

The second upper electrode ELU2 may be disposed on the first upper electrode ELU1. The second upper electrode ELU2 may have a structural characteristic similar to that of the first upper electrode ELU1. For example, the second upper electrode ELU2 may cover the first upper protruding portion structure formed by the first upper electrode ELU1. The second upper electrode ELU2 may entirely cover the first upper protruding portion structure.

The second upper electrode ELU2 may have a shape that matches the shape of an upper surface of the first upper electrode ELU1. For example, the second upper electrode ELU2 may include a second upper protruding portion structure that generally matches a shape of the first upper protruding portion structure. According to an embodiment, the second upper electrode ELU2 may be formed after the first upper electrode ELU1 is disposed. At this time, the second upper electrode ELU2 may be formed through a process of sputtering or the like and may be relatively thin. For example, the second upper electrode ELU2 may have a thickness that is less than that of the intermediate electrode ELM. Accordingly, the second upper electrode ELU2 may be formed to be relatively thin along an upper surface of the first upper electrode ELU1, and the second upper electrode ELU2 may be formed to have the second upper protruding portion structure having the same contours as the first upper protruding portion structure. In some embodiments, the second upper electrode ELU2 may be conformally formed on the first upper electrode ELU1. The second upper electrode ELU2 may have a constant thickness. The second upper protruding portion structure of the second upper electrode ELU2 according to an embodiment may be manufactured without performing an additional heat treatment process or an etching process.

The second upper electrode ELU2 may include a transparent conductive material. For example, the second upper electrode ELU2 may include one or more of the transparent conductive materials described above with reference to the upper electrode ELU. For example, the second upper electrode ELU2 may include ITO. However, the disclosure is not necessarily limited thereto.

According to the present embodiment, the intermediate electrode ELM and the first upper electrode ELU1 including different materials may respectively form a reflective layer. Experimentally, reflective materials may have different reflectances for each wavelength band. That is, as the intermediate electrode ELM and the first upper electrode ELU1 including different reflective materials respectively form the reflective layer, reflection efficiency may be improved with respect to a wide wavelength band.

In addition, in the present embodiment, the protruding portion 200 and first and second upper protruding portion structures are formed, and thus light emission efficiency, a viewing angle characteristic, and the like may be improved.

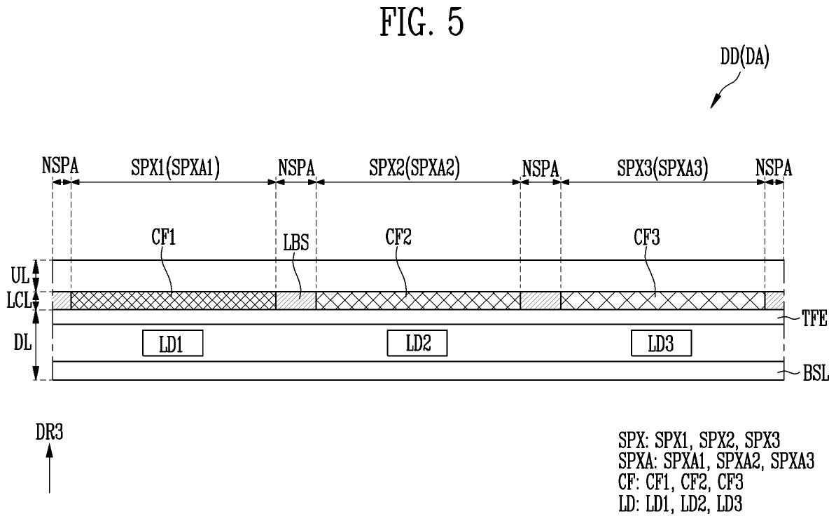

With reference to FIGS. 5 to 7, a display device DD including other layers on the display layer DL according to an embodiment is described. Content that may overlap the content described above will be briefly described or will be omitted to avoid redundancy.

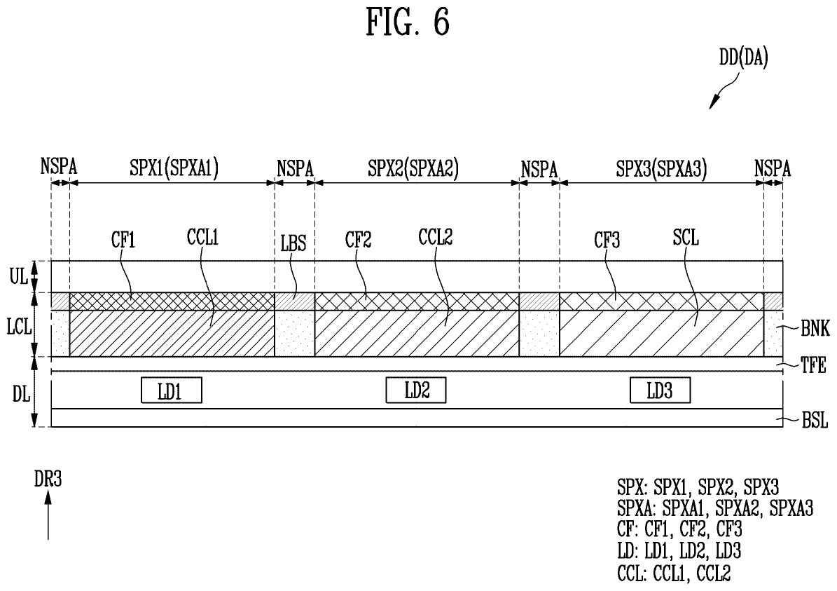

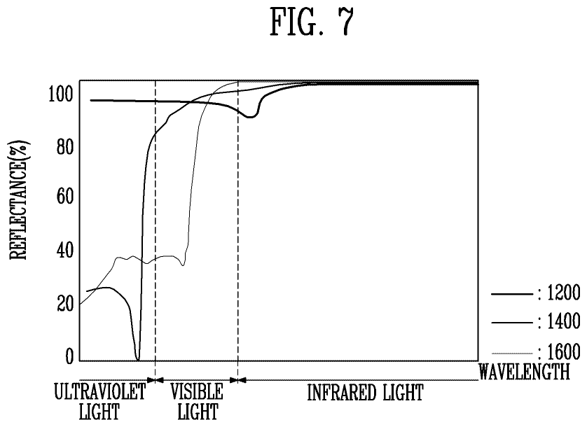

FIGS. 5 and 6 are schematic cross-sectional views illustrating a display device according to an embodiment. FIGS. 5 and 6 schematically show the display layer DL, a light controlling layer LCL, and an upper layer UL included in the display device DD in the display area DA. FIG. 7 is a graph illustrating a reflectance characteristic of various metal materials for each wavelength band of light.

First, with reference to FIG. 5, the display device DD according to an embodiment is described.

According to an embodiment, the sub-pixel SPX of the display device DD may form a sub-pixel area SPXA. The sub-pixel areas SPXA may be an area where light of a color is emitted. According to an embodiment, the display device DD may further include a non-sub-pixel area NSPA in which light of a color is not visible.

The sub-pixel area SPXA may include a first sub-pixel area SPXA1 formed by the first sub-pixel SPX1 and provided with light of a first color, a second sub-pixel area SPXA2 formed by the second sub-pixel SPX2 and provided with light of a second color, and a third sub-pixel area SPXA3 formed by the third sub-pixel SPX3 and provided with light of a third color.

According to an embodiment, the light emitting element LD may include a first light emitting element LD1 disposed in the first sub-pixel area SPXA1, a second light emitting element LD2 disposed in the second sub-pixel area SPXA2, and a third light emitting element LD3 disposed in the third sub-pixel area SPXA3.

According to an embodiment, the first to third light emitting elements LD1 to LD3 may be configured to emit light of different colors, respectively. For example, the first light emitting element LD1 may provide light of the first color in the first sub-pixel area SPXA1. The second light emitting element LD2 may provide light of the second color in the second sub-pixel area SPXA2. The third light emitting element LD3 may provide light of the third color in the third sub-pixel area SPXA3.

The light controlling layer LCL may be disposed on the display layer DL. The light controlling layer LCL may include color filters CF and a light control structure LBS.

The color filters CF may include a first color filter CF1 disposed in the first sub-pixel area SPXA1, a second color filter CF2 disposed in the second sub-pixel area SPXA2, and a third color filter CF3 disposed in the third sub-pixel area SPXA3.

The first color filter CF1 may be disposed in the first sub-pixel area SPXA1. The first color filter CF1 may include a color filter material (for example, dye or pigment) that selectively transmits light of the first color (for example, red).

The second color filter CF2 may be disposed in the second sub-pixel area SPXA2. The second color filter CF2 may include a color filter material (for example, dye or pigment) that selectively transmits light of the second color (for example, green).

The third color filter CF3 may be disposed in the third sub-pixel area SPXA3. The third color filter CF3 may include a color filter material (for example, dye or pigment) that selectively transmits light of the third color (for example, blue).

The light control structure LBS may be placed in the non-sub-pixel area NSPA. The light control structure LBS may be formed by overlapping the first to third color filters CF1 to CF3. However, the disclosure is not limited thereto. For example, the light control structure LBS may include various light blocking materials (for example, a black matrix or the like).

The upper layer UL may be disposed in an upper portion based on the display direction of the display device DD and may include various layers. For example, the upper layer UL may include a cover window. The upper layer UL may further include various functional film layers (low-reflective film and the like). However, the disclosure is not limited to a specific example.

Next, with reference to FIG. 6, a display device DD according to another embodiment is described. Any content that may overlap the content described above will be briefly described or omitted to avoid redundancy.

According to an embodiment, the first to third light emitting elements LD1 to LD3 may be configured to provide light of the same color. For example, each of the first to third light emitting elements LD1 to LD3 may provide light of the third color.

According to an embodiment, the light controlling layer LCL may further include color conversion layers CCL, a scattering layer SCL, and a bank BNK.

According to an embodiment, a capping layer and the like may be further disposed on the color conversion layers CCL and the scattering layer SCL.

The color conversion layer CCL may be patterned in the display area DA. The color conversion layer CCL may be disposed in an area surrounded by the bank BNK. The color conversion layer CCL may not overlap the bank BNK in plan view.

The color conversion layer CCL may be configured to change the color of light. For example, the color conversion layer CCL may include a first color conversion layer CCL1 and a second color conversion layer CCL2.

The first color conversion layer CCL1 may be a layer for forming the first sub-pixel SPX1. The first color conversion layer CCL1 may include first color conversion particles that convert light (for example, light including a light component of the third color) provided by the light emitting element LD into the light of the first color. For example, the first color conversion layer CCL1 may include a first quantum-dot that converts the light of the third color into the light of the first color. The first quantum dot may absorb the light of the third color and shift a wavelength according to energy transition to emit the light of the first color. The first quantum-dot may be prepared by being dispersed in a matrix layer of an organic material or the like included in the first color conversion layer CCL1.

The second color conversion layer CCL2 may be a layer for forming the second sub-pixel SPX2. The second color conversion layer CCL2 may include second color conversion particles that convert light (for example, the light including the light component of the third color) provided by the light emitting element LD into the light of the second color. For example, the second color conversion layer CCL2 may include a second quantum-dot that converts the light of the third color into the light of the second color. The second quantum-dot may absorb the light of the third color and shift a wavelength according to energy transition to emit the light of the second color. The second quantum-dot may be prepared by being dispersed in a matrix layer of an organic material or the like included in the second color conversion layer CCL2.

The scattering layer SCL may be patterned in the display area DA. The scattering layer SCL may be disposed in an area surrounded by the bank BNK. The scattering layer SCL may not overlap the bank BNK in plan view.

The scattering layer SCL may be a layer for improving light emission efficiency of the display device DD and improving a viewing angle characteristic. The scattering layer SCL may include a scatterer. The scatterer may be prepared by being dispersed in a matrix layer of an organic material (for example, a transparent organic material) or the like included in the scattering layer SCL. According to an embodiment, the scatterer may include one or more of a group of titanium oxide (TiOx), silica (SiOx) (for example, a silica bead, a hollow silica, or the like), zirconium oxide (ZrOx), aluminum oxide (AlxOy), indium oxide (InxOy), zinc oxide (ZnOx), tin oxide (SnOx), and antimony oxide (SbxOy). However, the disclosure is not limited thereto.

The bank BNK may be patterned in the display area DA. The bank BNK may form an opening. The bank BNK may have a thickness (for example, the third direction DR3) and be disposed on the base layer BSL around the opening.

The bank BNK may include one or more of a group of acrylic resin, epoxy resin, phenol resin, polyamide resin, and polyimide resin. According to an embodiment, the bank BNK may include a light blocking material (for example, a black matrix). However, the disclosure is not limited thereto.

As described above, the intermediate electrode ELM that functions as a reflective layer to improve light output efficiency of the light emitting element LD may include aluminum (Al).

In conjunction with FIG. 7, a technical effect that may be provided by the display device DD when the intermediate electrode ELM includes aluminum (Al) is described.

In FIG. 7, a (1-1)-th graph 1200 represents a reflectance % of aluminum (Al) for an applied light wavelength band, a (1-2)-th graph 1400 represents a reflectance % of silver (Ag) for the applied light wavelength band, and a (1-3)-th graph 1600 represents a reflectance % of gold (Au) for the applied light wavelength band. The (1-1)-th graph 1200, the (1-2)-th graph 1400, and the (1-3)-th graph 1600 are respectively represented by lines having different thicknesses.

According to an embodiment, the display device DD is configured to provide light of a visible light wavelength band in the first to third sub-pixel areas SPXA. Referring to FIG. 7, it may be seen that a reflectance of aluminum (Al) is generally excellent in the visible light wavelength band. In particular, it may be confirmed that aluminum (Al) has an excellent reflectance compared to silver (Ag) and gold (Au) in a blue wavelength band of the visible light wavelength band. Accordingly, according to an embodiment, when the intermediate electrode ELM includes aluminum (Al), the display device DD may have excellent light efficiency even in a relatively low wavelength band (for example, the third sub-pixel SPX3).

In addition, according to the embodiment described above with reference to FIG. 6, each of the first to third light emitting elements LD1 to LD3 may be configured to emit blue light. The blue light emitted by the first light emitting element LD1 may be converted to red by the first color conversion layer CCL1 in the first sub-pixel area SPXA1 and output to the outside, the blue light emitted by the second light emitting element LD2 may be converted to red by the second color conversion layer CCL2 in the second sub-pixel area SPXA2 and output to the outside, and the blue light emitted by the third light emitting element LD3 may be output to the outside without color conversion in the third sub-pixel area SPXA3. That is, since the blue light from each of the first to third light emitting elements LD1 to LD3 may be recycled by the intermediate electrode ELM including aluminum (Al) and the intermediate electrode ELM may be formed based on aluminum (Al), which has a high reflection efficiency in relation to the blue light, light emission efficiency of the display device DD may be further improved.

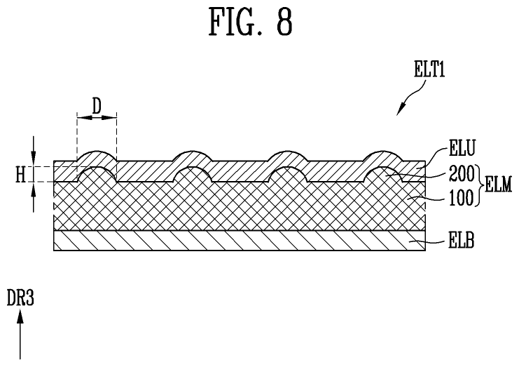

With reference to FIGS. 8 to 11, a physical characteristic of the intermediate electrode ELM including the protruding portion 200 is described.

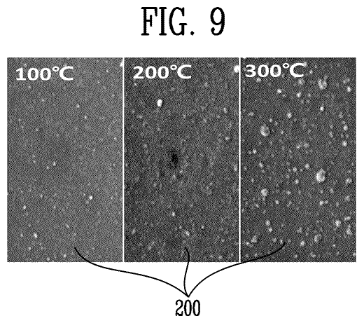

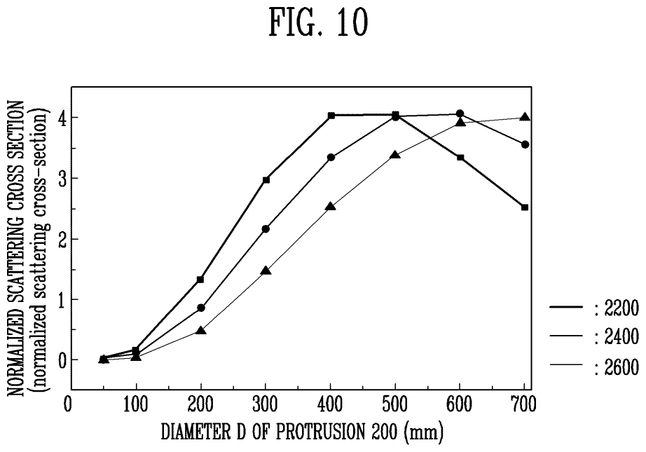

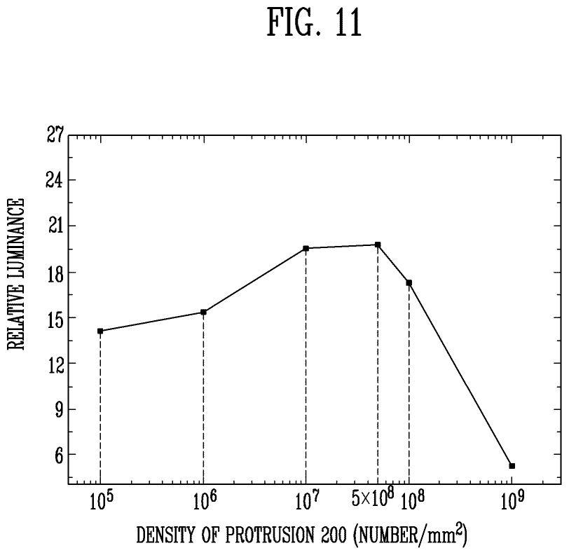

FIG. 8 is a schematic enlarged cross-sectional view illustrating a first electrode according to an embodiment. FIG. 9 illustrates a plane image of an intermediate electrode according to a heat treatment process temperature for manufacturing the intermediate electrode according to an embodiment. FIG. 10 is a graph illustrating a normalized scattering cross section for each wavelength band of light according to a diameter of a protruding portion of an intermediate electrode according to an embodiment. FIG. 11 is a graph illustrating a relative luminance of light provided according to a density of a protruding portion of an intermediate electrode according to an embodiment.

For reference, an experimental example disclosed in FIGS. 9 to 11 is measured using the first electrode ELT1 manufactured according to an embodiment. In FIGS. 9 to 11, the lower electrode ELB included in the first electrode ELT1 includes (ITO), the intermediate electrode ELM includes aluminum (Al), and the upper electrode ELU includes (ITO).

Referring to FIG. 8, the first electrode ELT1 may include the lower electrode ELB, the intermediate electrode ELM disposed on the lower electrode ELB and including the intermediate base electrode 100 and the protruding portion 200 that are integral with each other, and the upper electrode ELU disposed on the intermediate electrode ELM.

According to an embodiment, the protruding portion 200 may have a diameter D and a height H as indicated in FIG. 8.

The diameter D may be defined on the plane that is parallel to the plane in which the base layer BSL is disposed (for example, a plane defined by the first direction DR1 and the second direction DR2). The diameter D may be defined as the largest diameter of the protruding portion 200 in plan view. For example, when the protruding portion 200 has an elliptical shape in a plan view, the diameter D may be a semi-major axis. In a plan view, when the protruding portion 200 has a somewhat irregular shape, the diameter D may be the largest value among distances between a first point of the protruding portion 200 and a second point spaced apart from the first point.

The height H may be defined in the thickness direction (for example, the third direction DR3) of the base layer BSL. The height H may be a distance between an upper surface of the intermediate base electrode 100, which is generally flat, and the thickest point of the protruding portion 200.

According to an embodiment, the diameter D may be about 400 nm to 1000 nm. The diameter D may be about 400 nm to 600 nm.

According to an embodiment, the height H may be about half the diameter D. For example, the height H may be about 200 nm to 500 nm. The height H may be about 200 nm to 300 nm.

As described above, the protruding portion 200 according to an embodiment may be formed by performing a heat treatment process on the intermediate base electrode 100.

According to an embodiment, the protruding portion 200 may be formed through a heat treatment process of a temperature range of 100° C. to 300° C., or according to an embodiment, the protruding portion 200 may be formed through a heat treatment process of a temperature range of 100° C. to 200° C. Accordingly, the diameter D of the protruding portion 200 may be defined to have a relatively excellent normalized scattering cross-sectional view, and a density of the protruding portion 200 may be defined to have a relatively excellent luminance characteristic.

For example, a temperature of the heat treatment process may be a process environment temperature applied to the intermediate base electrode 100 when or after the intermediate base electrode 100 is formed. For example, the temperature of the heat treatment process may be a temperature of a substrate on which the intermediate base electrode 100 is disposed (for example, the base layer BSL as a base portion on which the intermediate base electrode 100 is formed), and the temperature of the heat treatment process may be a temperature in a chamber where the heat treatment process for the intermediate base electrode 100 is performed. However, the disclosure is not limited thereto.

FIG. 9 illustrates a plane image of the intermediate electrode 100 according to the temperature of the heat treatment process. FIG. 9 is a plane image (that is, a scanning electron microscopy (SEM) image) of the intermediate electrode 100 measured by SEM.

Referring to FIG. 9, it may be confirmed that the diameter D of the protruding portion 200 increases as the temperature of the heat treatment process increases. Meanwhile, according to an embodiment, the protruding portions 200 may be randomly formed on the intermediate base electrode 100, and thus the protruding portions 200 may have different sizes.

The diameter D of the protruding portions 200 and the density of the protruding portions 200 according to the heat treatment process temperature are shown in Table 1 below.

TABLE 1

| | Diameter of protruding | Density of protruding |
|---|---|---|
| Division | portion 200 | portion 200 |
| 100° C. | 400 nm or less | 10⁷ or less (number/mm²) |
| 200° C. | 600 nm or less | 5 × 10⁷ or less (number/mm²) |
| 300° C. | 1000 nm or less | 10⁸ or less (number/mm²) |

The diameter D of the protruding portions 200 may be calculated by obtaining an SEM image of a portion of an area where the protruding portions 200 formed on the intermediate base electrode 100 are disposed and measuring the diameter of the protruding portions 200 in the obtained SEM image. The density of the protruding portions 200 may be calculated by obtaining an SEM image of a portion of an area where the protruding portions 200 formed on the intermediate base electrode 100 are disposed and counting the number of protruding portions 200 in the obtained SEM image.

Referring to FIG. 10, a light efficiency characteristic according to the diameter D of the protruding portions 200 is disclosed. In FIG. 10, a (2-1)-th graph 2200 represents a size of the normalized scattering cross section according to the diameter D of the protruding portion 200 when blue light (light of a wavelength of about 476 nm) is applied, a (2-2)-th graph 2400 represents a size of the normalized scattering cross section according to the diameter D of the protruding portion 200 when green light (light of a wavelength of about 524 nm) is applied, and a (2-3)-th graph 2600 represents a size of the normalized scattering cross section according to the diameter D of the protruding portion 200 when red light (light of a wavelength of about 616 nm) is applied. The (2-1)-th graph 2200, the (2-2)-th graph 2400, and the (2-3)-th graph 2600 are respectively displayed as lines having different thicknesses.

The normalized scattering cross section is a value obtained by calculating a scattering cross section value as a normalized value. Based on the normalized scattering cross section, a tendency of each data according to the diameter D of the protruding portion 200 may be understood. The scattering cross section refers to the number of particles scattered with respect to a certain angle when two particles are scattered by repulsion due to long-distance interaction, and is well-understood in the field. That is, a value of the scattering cross section may correspond to the number of scattering particles, and it may be understood that the value of the scattering cross section increases, the light emission efficiency increases.

According to an embodiment, data of the scattering cross section may be measured by light scattering measurement equipment or the like generally known in the art.

According to an embodiment, it may be seen that when the diameter D of the protruding portion 200 is 400 nm to 600 nm, the value of the normalized scattering cross section is generally high. In particular, when the diameter D of the protruding portion 200 exceeds 600 nm, a scattering cross section value of green light and blue light may be decreased, and when the diameter D of the protruding portion 200 is less than 400 nm, a scattering cross section value of red light, green light, and blue light may not be sufficiently large.

Accordingly, according to an embodiment, in order to provide an excellent scattering cross section value defined in the display device DD, the diameter D of the protruding portion 200 may be about 400 nm to 600 nm, and the temperature of the heat treatment process for forming the protruding portion 200 may be about 100° C. to about 200° C. so that the diameter D of the protruding portion 200 satisfies the numerical range described above.

Referring to FIG. 11, a light efficiency characteristic according to the density of the protruding portions 200 is disclosed. In FIG. 11, relative luminance data according to the number of protruding portions 200 per unit area (e.g., mm²) is disclosed. In FIG. 11, luminance data is obtained at each density of the protruding portions 200, and each luminance data is displayed as a relative value according to the density of the protruding portions 200.

According to an embodiment, the relative luminance may be measured by a luminance measurement device generally known in the art.

According to an embodiment, it may be seen that when the density [number/mm²] of the protruding portions 200 is 10⁷ to 10⁸, or when the density [number/mm²] of the protruding portions 200 is 10⁷ to 5×10⁷, a value of the relative luminance is generally high.

Accordingly, according to an embodiment, in order to provide a high relative luminance value defined in the display device DD, the density of the protruding portion 200 may be 10⁷ to 10⁸, and the temperature of the heat treatment process for forming the protruding portion 200 may be about 100° C. to about 300° C. so that the density of the protruding portion 200 satisfies the numerical range described above. Alternatively, according to an embodiment, in order to provide a high relative luminance value defined in the display device DD, the density of the protruding portion 200 may be 10⁷ to 5×10⁷, and the temperature of the heat treatment process for forming the protruding portion 200 may be about 100° C. to about 200° C. so that the density of the protruding portion 200 satisfies the numerical range described above.

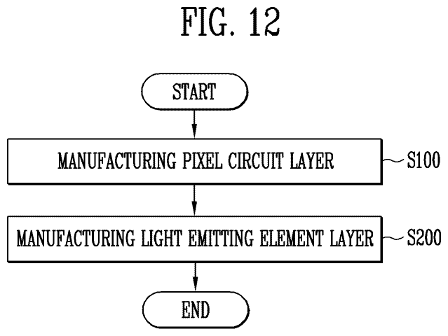

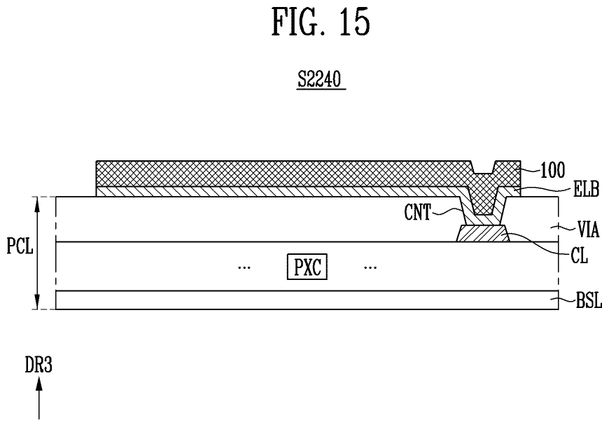

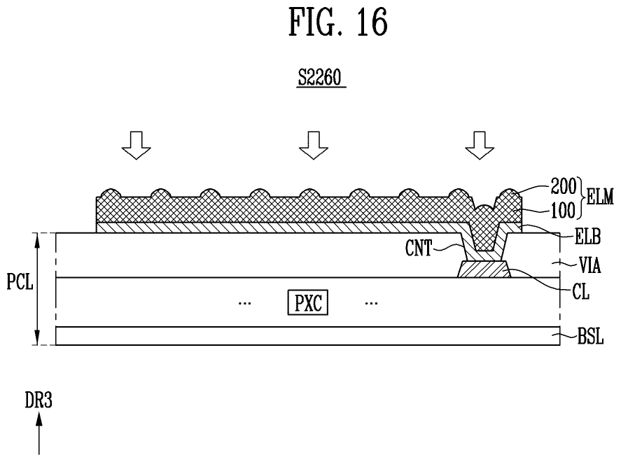

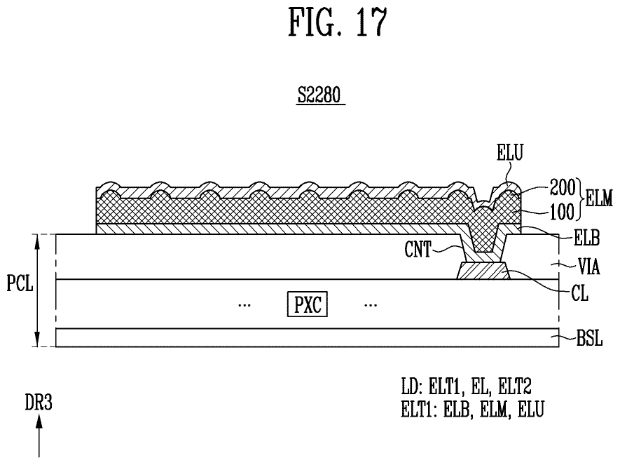

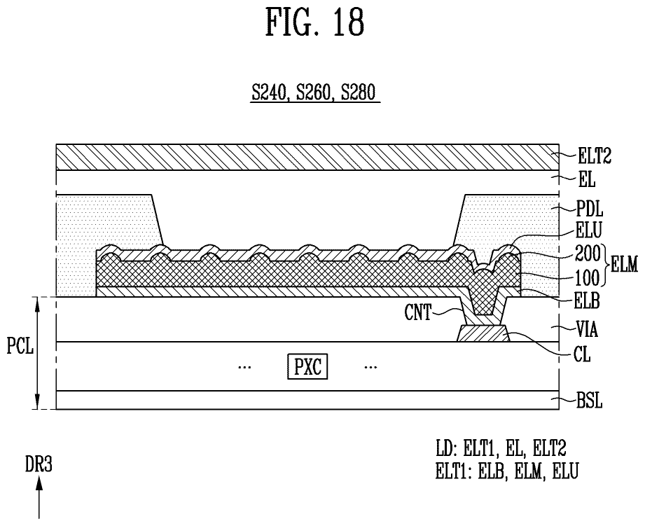

With reference to FIGS. 12 to 18, a method of manufacturing a display device DD according to an embodiment is described. Any content that may overlap the content described above will be briefly described or omitted to avoid redundancy.

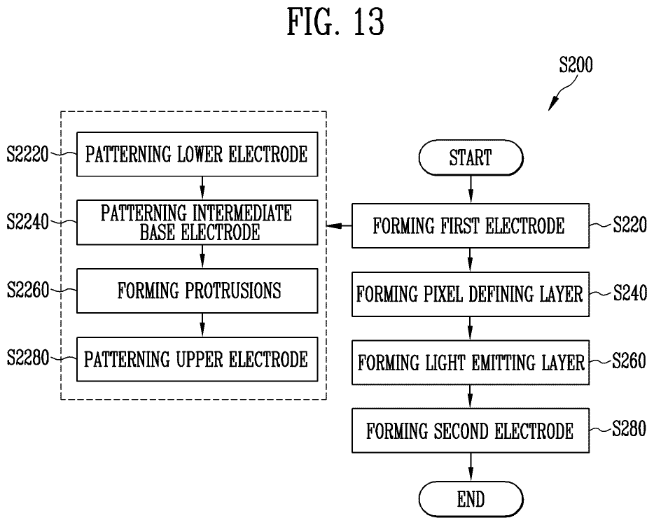

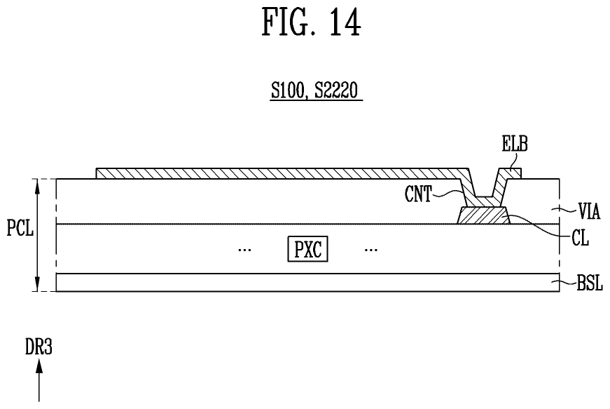

FIGS. 12 to 18 shows a method of manufacturing the display device DD according to the embodiment described above with reference to FIG. 2. FIG. 12 is a flowchart illustrating a method of manufacturing a display device according to an embodiment. FIG. 13 is a flowchart illustrating the method of manufacturing a light emitting element layer according to an embodiment. FIGS. 14 to 18 are schematic cross-sectional views for each process stage illustrating a method of manufacturing a display device according to an embodiment.

Referring to FIG. 12, a method of manufacturing a display device DD according to an embodiment may include manufacturing the pixel circuit layer (S100) and manufacturing the light emitting element layer (S200).

Referring to FIG. 13, manufacturing the light emitting element layer (S200) may include forming the first electrode (S220), forming the pixel defining layer (S240), forming the light emitting layer (S260), and forming the second electrode (S280).

Referring to FIGS. 12 and 14, in manufacturing the pixel circuit layer (S100), the pixel circuit PXC and the conductive layer CL may be patterned on the base layer BSL, and the via layer VIA may be formed.

According to an embodiment, the conductive layer or the insulating layer on the base layer BSL may be formed using a typical process for manufacturing a semiconductor device. For example, the conductive layer or the insulating layer on the base layer BSL may be formed by a photolithography process, etched by various methods (wet etching, dry etching, and the like), and may be deposited by various methods (sputtering, chemical vapor deposition, and the like). The disclosure is not necessarily limited to a specific method of forming the conductive layer or the insulating layer.

Referring to FIGS. 12 and 13 to 17, in manufacturing the light emitting element layer (S200), forming the first electrode (S220) may be performed.

According to an embodiment, forming the first electrode (S220) may include patterning the lower electrode (S2220), patterning the intermediate base electrode (S2240), forming the protruding portions (S2260), and patterning the upper electrode (S2280).

Referring to FIGS. 12 to 14, in patterning the lower electrode (S2220), a hole may be formed through the via layer VIA by removing a section of the via layer VIA, and the lower electrode ELB may be formed on the via layer VIA. As depicted in FIG. 14, the lower electrode ELB may be disposed at the bottom and on the sidewalls of the hole.

In this step S2220, as the lower electrode ELB is patterned, the contact portion CNT may be formed, and the lower electrode ELB may be electrically connected to the conductive layer CL through the contact portion CNT. Accordingly, the lower electrode ELB may be electrically connected to the pixel circuit PXC through the conductive layer CL.

Referring to FIGS. 12, 13, and 15, in patterning the intermediate base electrode (S2240), the intermediate base electrode 100 may be patterned on the lower electrode ELB.

In this step S2240, the intermediate base electrode 100 may be formed on an upper surface of the lower electrode ELB, and a base for forming the protruding portions 200 in a subsequent process may be formed. The intermediate base electrode 100 may be formed to have a thickness greater than that of the lower electrode ELB.

Referring to FIGS. 12, 13, and 16, in forming the protruding portions (S2260), a heat treatment process may be performed on the intermediate base electrode 100, and thus the protruding portions 200 may be formed.

In this step S2260, the temperature range for performing the heat treatment process may be 100° C. to 300° C. Alternatively, according to an embodiment, the temperature range for performing the heat treatment process may be 100° C. to 200° C.

As described above, as the temperature range for performing the heat treatment process satisfies the numerical range described above, the size and the density of the protruding portions 200 may be prepared to satisfy the appropriate numerical range, and thus light emission efficiency of the light emitting element LD may be further improved.

According to an embodiment, forming the protruding portions (S2260) may be performed after patterning the intermediate base electrode (S2240), but the disclosure is not limited thereto.

For example, according to an embodiment, “patterning” the intermediate base electrode (S2240) and forming the protruding portions (S2260) may be performed with one process. A process temperature range for the heat treatment process for forming the protruding portions 200 may be achieved in a process environment for patterning the intermediate base electrode 100. For example, the temperature in the chamber in which the deposition process for forming the intermediate base electrode 100 is performed may be adjusted, and thus a deposition process of the intermediate base electrode 100 and the heat treatment process for forming the protruding portions 200 may be performed simultaneously. In this case, the protruding portions 200 may be formed in a process section that is substantially the same as a process in which the intermediate base electrode 100 is formed. In this case, a process may be further simplified, a process efficiency may be improved, and a process cost may be further reduced.

Referring to FIGS. 12, 13, and 17, in patterning the upper electrode (S2280), the upper electrode ELU may be patterned on the intermediate electrode ELM.

In this step S2280, the upper electrode ELU may be formed based on a process of sputtering or the like and may be formed to have a thickness that is less than that of the intermediate electrode ELM. Accordingly, the upper electrode ELU may be formed along a surface formed by the protruding portion 200, and the upper electrode ELU may include a protruding portion structure having a surface contour that generally matches the contours of the protruding portion 200.

Referring to FIGS. 12, 13, and 18, in forming the pixel defining layer (S240), the pixel defining layer PDL may be patterned to cover a portion of the first electrode ELT1.

In this step S240, the pixel defining layer PDL may expose an upper surface of the first electrode ELT1 (for example, an upper surface of the upper electrode ELU), and may cover an edge of the first electrode ELT1.

Referring to FIGS. 12, 13, and 18, in forming the light emitting layer (S260), the light emitting layer EL may be formed so that at least a portion of the light emitting layer EL is electrically connected to the first electrode ELT1.

In this step S260, layers for forming the light emitting layer EL described above with reference to FIG. 4 may be sequentially formed. For example, each of the layers forming the light emitting layer EL may be formed through a process of vacuum deposition, inkjet printing, or the like.

Referring to FIGS. 12, 13, and 18, in forming the second electrode (S280), the second electrode ELT2 may be formed to be electrically connected to the light emitting layer EL.

In this step S280, the second electrode ELT2 may be deposited on the entire surface, and the common electrode for the sub-pixels SPX may be formed. Accordingly, the first electrode ELT1, the light emitting layer EL, and the second electrode ELT2 may form the light emitting element LD.

Thereafter, according to an embodiment, the capping layer CPL and the encapsulating layer TFE may be formed on the second electrode ELT2, and thus the light emitting element layer LEL according to an embodiment may be provided. According to an embodiment, the light controlling layer LCL, the upper layer UL, and the like may be further disposed on the light emitting element layer LEL, and thus the display device DD according to an embodiment may be provided.

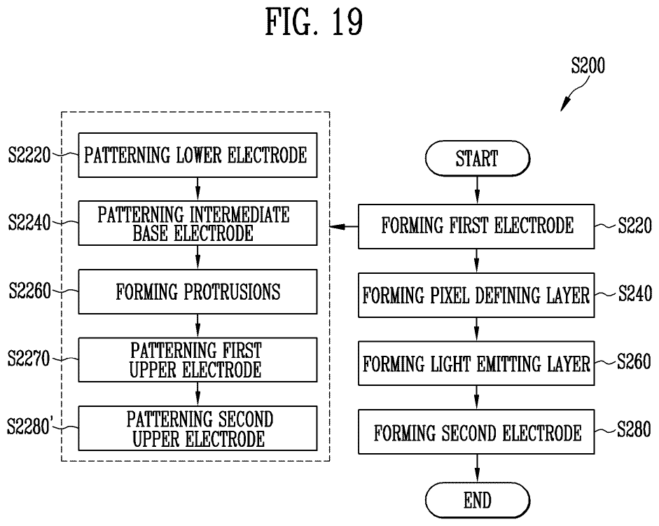

With reference to FIGS. 19 to 21, a method of manufacturing a display device DD according to an embodiment is described. Any content that may overlap the content described above will briefly described or omitted to avoid redundancy.

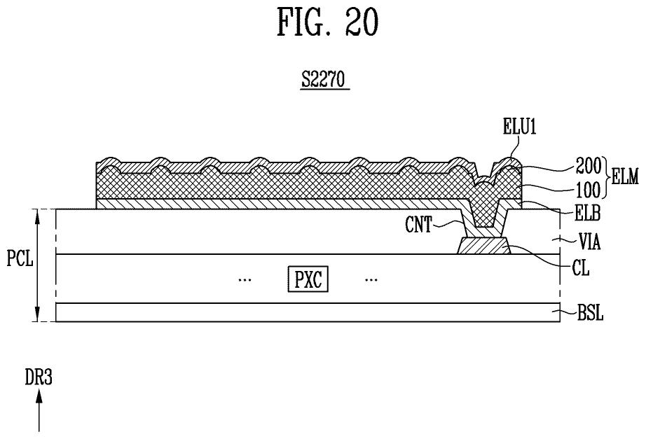

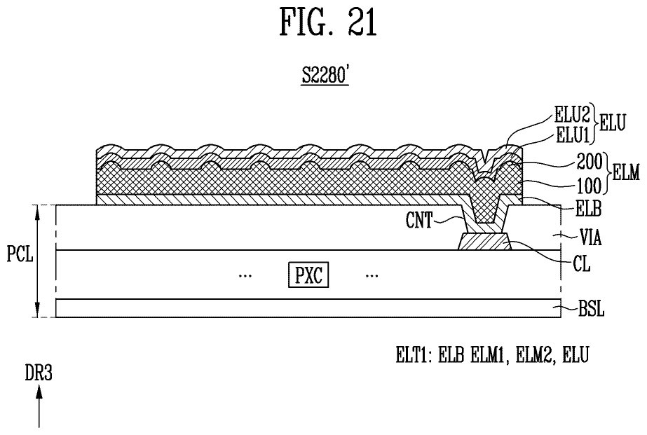

FIGS. 19 to 21 illustrate a method of manufacturing the display device DD according to the embodiment described above with reference to FIG. 3. FIG. 19 is a flowchart illustrating the process of manufacturing a light emitting element layer according to an embodiment. FIGS. 20 and 21 are schematic cross-sectional views for each process step illustrating a method of manufacturing a display device according to an embodiment.

The method of manufacturing the display device DD according to this embodiment is different from the method of manufacturing the display device DD described above, in that forming the first electrode (S220) includes patterning the first upper electrode (S2270) and patterning the second upper electrode (S2280′).

Referring to FIGS. 19 and 20, similarly to the embodiment described above, the intermediate electrode ELM including the protruding portion 200 may be manufactured based on a heat treatment process. After the protruding portion 200 is formed, patterning the first upper electrode (S2270) may be performed.

In this step S2270, the first upper electrode ELU1 covering the protruding portions 200 may be formed. The first upper electrode ELU1 may have a thickness that is less than that of the intermediate electrode ELM. Accordingly, when the first upper electrode ELU1 is formed, an upper protruding portion structure having contours that match the contours of the protruding portion 200 may be formed. That is, the first upper electrode ELU1 may form a protruding portion structure without performing an additional heat treatment process.

Patterning the second upper electrode (S2280′) may involve the same process as patterning the upper electrode (S2280) shown in FIG. 13, and the substantially same technical feature as the content described above may be applied.

For example, referring to FIGS. 19 and 21, in patterning the second upper electrode (S2280′), the second upper electrode ELU2 having a thickness less than that of the intermediate electrode ELM may be formed based on a process of sputtering or the like, and an upper protruding portion structure having similar contours as the protruding portion 200 may be formed. That is, the second upper electrode ELU2 may form a protruding portion structure without performing an additional heat treatment process.

Accordingly, the first electrode ELT1 including the upper electrode ELU made of two or more layers may be manufactured. As described above, since the first electrode ELT1 according to an embodiment includes the intermediate electrode ELM manufactured based on a heat treatment process, a technical effect in which light emission efficiency is improved may be provided.

Hereinafter, an electronic device 1000 including the display device DD in accordance with an embodiment will be described.

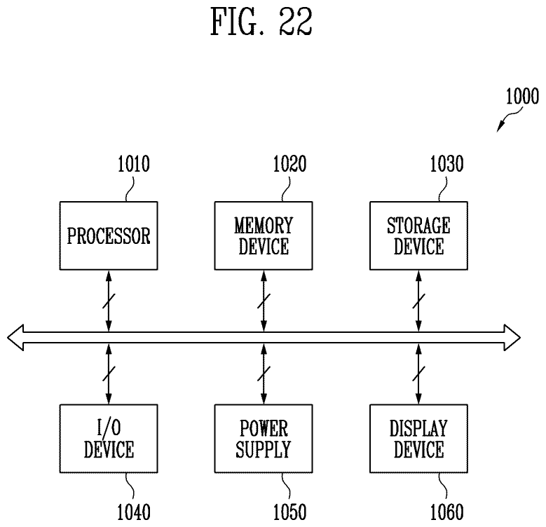

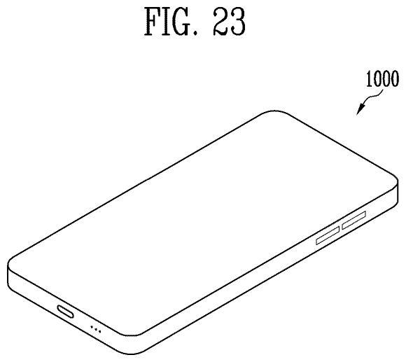

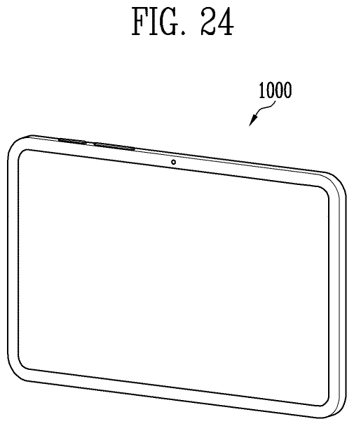

FIG. 22 is a schematic block diagram illustrating an electronic device 1000 including a display device in accordance with an embodiment. FIG. 23 is a schematic diagram illustrating an example where the electronic device 1000 of FIG. 21 is implemented as a smartphone. FIG. 24 is a schematic diagram illustrating an example where the electronic device 1000 of FIG. 21 is implemented as a tablet computer.

Referring to FIGS. 22 to 24, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 23, the electronic device 1000 may be a smartphone. In an embodiment, as illustrated in FIG. 24, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to image data signals and/or control signals from the processor 1010. The display device 1060 may be connected to other components through the buses or other communication links.

As described above, although the disclosure is described with reference to specific embodiments, those skilled in the art or those having a common knowledge in the art will understand that the disclosure may be variously modified and changed without departing from the spirit and technical area of the disclosure described in the claims which will be described later.

Therefore, the technical scope of the disclosure should not be limited to the contents described in the detailed description of the specification, but should be defined by the claims.

What is claimed is:

1. A display device comprising:
a base layer; and
a light emitting element disposed on the base layer, and including a first electrode, a light emitting layer electrically connected to the first electrode, and a second electrode electrically connected to the light emitting layer,
wherein the first electrode includes a lower electrode disposed between the light emitting layer and the base layer, an intermediate electrode on the lower electrode, and an upper electrode on the intermediate electrode, and
the intermediate electrode includes an intermediate base electrode and a protruding portion protruding in a thickness direction of the base layer, wherein the intermediate electrode includes aluminum (Al).

2. The display device according to claim 1, wherein the protruding portion forms a reflective surface extending in a direction inclined with respect to the thickness direction of the base layer.

3. The display device according to claim 1, wherein a diameter of the protruding portion is 400 nm to 600 nm, and
a height of the protruding portion is 200 nm to 300 nm.

4. The display device according to claim 1, wherein the protruding portion includes a plurality of protruding portions, and
the plurality of protruding portions are formed to have a density of 10⁷ to 10⁸ per unit area [mm²] on the intermediate base electrode.

5. The display device according to claim 1, wherein the protruding portion includes a plurality of protruding portions, and
the plurality of protruding portions are randomly formed on the intermediate base electrode.

6. The display device according to claim 1, wherein the lower electrode and the upper electrode include a transparent conductive material.

7. The display device according to claim 1, wherein the upper electrode has a thickness that is less than that of the intermediate electrode, and
the upper electrode forms a protruding portion structure that matches the contours of the protruding portion.

8. The display device according to claim 1, wherein the upper electrode includes a first upper electrode and a second upper electrode including different materials,
the first upper electrode has a thickness less than that of the intermediate electrode and forms a first protruding portion structure having contours that match the contours of the protruding portion, and
the second upper electrode has a thickness less than that of the intermediate electrode and forms a second protruding portion structure having contours that match the contours of the protruding portion.

9. The display device according to claim 1, further comprising:
a first sub-pixel area where light of a first color is provided;
a second sub-pixel area where light of a second color is provided; and
a third sub-pixel area where light of a third color is provided,
wherein the light emitting element includes a first light emitting element in the first sub-pixel area, a second light emitting element in the second sub-pixel area, and a third light emitting element in the third sub-pixel area,
the first light emitting element provides the light of the first color, the second light emitting element provides the light of the second color, and the third light emitting element provides the light of the third color.

10. A display device comprising:
a base layer; and
a light emitting element disposed on the base layer, and including a first electrode, a light emitting layer electrically connected to the first electrode, and a second electrode electrically connected to the light emitting layer,
wherein the first electrode is disposed between the light emitting layer and the base layer, and includes a lower electrode, an intermediate electrode on the lower electrode, and an upper electrode on the intermediate electrode,
the intermediate electrode includes an intermediate base electrode layer and a protruding portion protruding in a thickness direction of the base layer, and
the protruding portion has a diameter of 400 nm to 600 nm in plan view.

11. A method of manufacturing a display device, the method comprising:
forming a first electrode on a base layer;
forming a light emitting layer on the first electrode; and
forming a second electrode on the light emitting layer,
wherein forming the first electrode comprises:
patterning a lower electrode on the base layer;
patterning an intermediate base electrode on the lower electrode;
forming protruding portions on the intermediate base electrode by performing a heat treatment process on the intermediate base electrode; and
patterning an upper electrode on the protruding portions and the intermediate base electrode.

12. The method according to claim 11, wherein the intermediate base electrode and the protruding portions include aluminum (Al), and
the lower electrode and the upper electrode include indium tin oxide (ITO).

13. The method according to claim 11, wherein a temperature range at which the heat treatment process is performed is 100° C. to 300° C.

14. The method according to claim 11, wherein forming the protruding portions comprises patterning the protruding portions on the intermediate base electrode without performing an etching process.

15. The method according to claim 11, wherein patterning the upper electrode comprises forming a protruding portion structure by the upper electrode without performing an additional heat treatment process.

16. The method according to claim 11, wherein forming the protruding portions is performed after patterning the intermediate base electrode.

17. The method according to claim 11, wherein forming the protruding portions and patterning the intermediate base electrode are performed in the same process.

18. The method according to claim 17, wherein forming the protruding portions comprises adjusting a temperature in a chamber for forming the intermediate base electrode.

19. The method according to claim 11, wherein the protruding portions and the intermediate base electrode form an intermediate electrode,
patterning the upper electrode comprises forming a first upper electrode and forming a second upper electrode on the first upper electrode,
forming the first upper electrode comprises forming a first protruding portion structure on the intermediate electrode without performing an additional heat treatment process, and
forming the second upper electrode comprises forming a second protruding portion structure on the intermediate electrode without performing an additional heat treatment process.

20. An electronic device, comprising:
a processor configured to provide input image data;
a display device configured to display an image based on the input image data, the display device including sub-pixel areas; and
a power supply configured to supply power to the display device,
wherein the display device comprises:
a base layer; and
a light emitting element disposed on the base layer, and including a first electrode, a light emitting layer electrically connected to the first electrode, and a second electrode electrically connected to the light emitting layer,
wherein the first electrode includes a lower electrode disposed between the light emitting layer and the base layer, an intermediate electrode on the lower electrode, and an upper electrode on the intermediate electrode, and
the intermediate electrode includes an intermediate base electrode and a protruding portion protruding in a thickness direction of the base layer, wherein the intermediate electrode includes aluminum (Al).
